(19) United States
(12) Patent Application Publication
(10) Pub. No.: US 2018/0190939 A1
(43) Pub. Date: Jul. 5, 2018

(54) PACKAGE STRUCTURES AND PACKAGE METHODS OF ORGANIC LIGHT EMITTING DIODE (OLED) PROTECTION FILMS

(71) Applicants: Haohan MIN, Shenzhen, Guangdong (CN); Wei YU, Shenzhen, Guangdong (CN)

(72) Inventors: Haohan MIN, Shenzhen, Guangdong (CN); Wei YU, Shenzhen, Guangdong (CN)

(73) Assignee: Wuhan China Star Optoelectronics Technology Co., Ltd., Wuhan, Hubei (CN)

(21) Appl. No.: 15/325,084

(22) PCT Filed: Jan. 7, 2017
(86) PCT No.: PCT/CN2017/070534

§ 371 Date: Jan. 9, 2017

(30) Foreign Application Priority Data
Dec. 27, 2016 (CN) 2016112251334

(51) Int. Cl. H01L 51/52; H01L 51/00; H01L 51/56

(52) U.S. Cl. CPC H01L 51/5253; H01L 51/0008; H01L 51/56; H01L 51/0024

(57) ABSTRACT

The present disclosure relates to a package structure and a package method of OLED protection films. The package structure includes: a mask and a glass substrate having at least one OLED component. The mask is configured with a hollow area having a dimension corresponding to the dimension of the OLED component. A gap is formed between a non-hollow area of the mask and a glass substrate. A groove is configured on the glass substrate and a location of the groove corresponds to the gap. A pillar is configured at one side of the mask facing toward the glass substrate. The pillar inserts into the groove when the mask and the glass substrate are aligned and bonded. The package structure and the package method of the OLED protection film may narrow down the black frame in the rim of the lighting surface, and contributes to the narrow-border design.

### BACKGROUND OF THE INVENTION

### 1. Field of the Invention

The present disclosure relates to organic light emitting diode (OLED) package technology, and more particularly to a package structure and a package method of OLED protection films.

### 2. Discussion of the Related Art

OLEDs are characterized by attributes, such as self-lighting, all-solid-state, wide viewing angle, quick response, and thus may be greatly adopted in flat displays. OLEDs have been viewed as the next-generation display products and technology after the liquid crystal display (LCD) and Plasma Display Panel (PDP). Currently, OLEDs have been widely adopted in the display and lighting fields.

Conventionally, a stack-layer structure, including one inorganic layer and one organic layer, is widely adopted by thin-film package of OLED. The inorganic layer generally adopts Plasma Enhanced Chemical Vapor Deposition (PECVD), Atomic layer deposition (ALD), and Plasma layer deposition (PLD) technologies. During the film-formation process of the inorganic layer, a mask is adopted. FIG. 1 is a cross-sectional view of the mask engaged with a glass substrate during the formation of the OLED protection film. A gap 3 may be formed between the mask 1 and the glass substrate 4 due to the design of the mask 1.

FIG. 2 is a schematic view of a portion of the formed OLED protection film. When the PECVD is adopted to form the protection film 5 on the OLED 2, the protection film 5 extends toward the gap, which affects the cutting location of the OLED sheet and widens a black frame in a rim of the OLED lighting surface. Such issue may make the narrow-border design more difficult. The reference numeral 10 in FIG. 1 relates to a hollow are of the mask.

### SUMMARY

The present disclosure relates to a package structure and package method of OLED protection films to prevent the protection film from extending toward the gap between the glass substrate and the mask during the formation of the OLED protection film.

In one aspect, package structure of organic light emitting diode (OLED) protection film includes: a mask and a glass substrate having at least one OLED component; the mask is configured with a hollow area having a dimension corresponding to the dimension of the OLED component, a gap is formed between a non-hollow area of the mask and a glass substrate, a groove is configured on the glass substrate and a location of the groove corresponds to the gap, a pillar is configured at one side of the mask facing toward the glass substrate, the pillar inserts into the groove when the mask and the glass substrate are aligned and bonded; when the protection film is formed on the OLED component, the pillar is configured to block the protection film; wherein the pillar on the mask is formed by depositing an inorganic material layer on the mask, and by applying exposure, lithography, and etching processes, a cross section of the pillar on the mask is trapezoid-shaped, and a shape of the groove on the glass substrate adapts to the shape of the pillar.

In another aspect, a package structure of organic light emitting diode (OLED) protection film includes: a mask and a glass substrate having at least one OLED component; the mask is configured with a hollow area having a dimension corresponding to the dimension of the OLED component, a gap is formed between a non-hollow area of the mask and a glass substrate, a groove is configured on the glass substrate and a location of the groove corresponds to the gap, a pillar is configured at one side of the mask facing toward the glass substrate, the pillar inserts into the groove when the mask and the glass substrate are aligned and bonded; when the protection film is formed on the OLED component, the pillar is configured to block the protection film.

Wherein the pillar on the mask is formed by depositing a material layer on the mask, and by applying exposure, lithography, and etching processes.

Wherein the pillar is formed by inorganic material.

Wherein a cross section of the pillar on the mask is trapezoid-shaped.

Wherein a shape of the groove on the glass substrate adapts to the shape of the pillar.

Wherein the groove on the glass substrate is configured to surround a rim of the OLED component.

Wherein a depth of the groove is in a range from 10 um to 20 um.

Wherein a height of the pillar is smaller than a sum of a thickness of the OLED component and a depth of the groove on the glass substrate such that the mask is closely bonded with the OLED component when the pillar inserts into the groove.

Wherein the inorganic material includes SiN, SiO, and SiON.

In another aspect, a package method of OLED protection film includes: forming a groove on a glass substrate having an OLED component arranged thereon; forming a pillar on a mask having a hollow area, a dimension of the hollow area correspond to the dimension of the OLED component; closely bonding the glass substrate having the groove and the mask having the pillar, when the pillar is inserted into the groove, and the mask is closely bonded with the OLED component, and forming a gap between a non-hollow area on the mask and the glass substrate; forming a protection film on the OLED component via the hollow area; wherein the pillar is configured to block the protection film.

Wherein the pillar on the mask is formed by depositing a material layer on the mask, and by applying exposure, lithography, and etching processes.

Wherein the pillar is formed by inorganic material.

Wherein a cross section of the pillar on the mask is trapezoid-shaped.

Wherein a shape of the groove on the glass substrate adapts to the shape of the pillar.

Wherein the groove on the glass substrate is configured to surround a rim of the OLED component.

wherein a depth of the groove is in a range from 10 um to 20 um.

Wherein a height of the pillar is smaller than a sum of a thickness of the OLED component and a depth of the groove on the glass substrate such that the mask is closely bonded with the OLED component when the pillar inserts into the groove.

Wherein the inorganic material includes SiN, SiO, and SiON.

In view of the above, the groove and the pillar that can be engaged with one other are configured on the glass substrate and the mask. The pillar may prevent the protection film from extending toward a gap between the glass substrate and the mask during the OLED protection film is formed. The package structure of the OLED protection film may narrow down the black frame in the rim of the lighting surface, and contributes to the narrow-border design.

### BRIEF DESCRIPTION OF THE DRAWINGS

Embodiments of the invention will now be described more fully hereinafter with reference to the accompanying drawings, in which embodiments of the invention are shown. Apparently, the accompanying drawings are only some embodiments of the claimed invention. Those of ordinary skill can derive other drawings from these drawings without creative efforts.

FIG. 1 is a cross-sectional view of the mask engaged with a glass substrate during the formation of the OLED protection film of a prior art.

FIG. 2 is a schematic view of a portion of the formed OLED protection film of the prior art shown in FIG. 1.

FIG. 3 is a schematic view of the separated mask and the glass substrate of the OLED protection film in accordance with one embodiment of the claimed invention.

FIG. 4 is a schematic view of the bonded mask and the glass substrate of FIG. 3.

FIG. 5 is a schematic view of the OLED protection film formed by the package structure in accordance with one embodiment of FIG. 3.

FIG. 6 is a schematic view of the package method of the OLED protection film in accordance with one embodiment of the claimed invention.

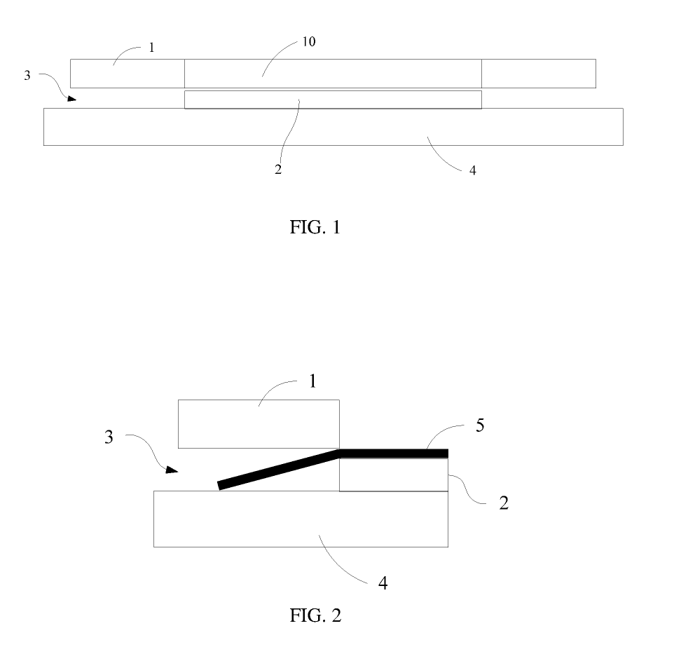

### DETAILED DESCRIPTION OF THE EMBODIMENTS

Embodiments of the invention will now be described more fully hereinafter with reference to the accompanying drawings, in which embodiments of the invention are shown.

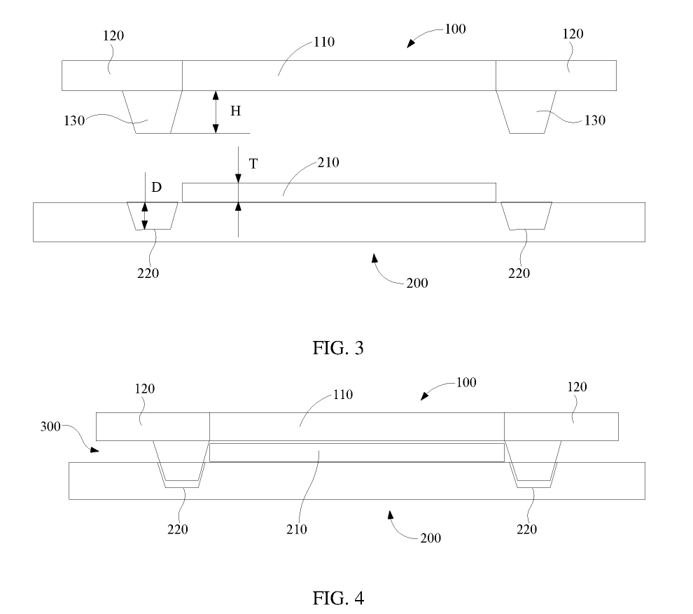

FIG. 3 is a schematic view of the separated mask and the glass substrate of the OLED protection film in accordance with one embodiment of the claimed invention. FIG. 4 is a schematic view of the bonded mask and the glass substrate of FIG. 3. The package structure includes a mask 100 and a glass substrate 200.

Specifically, the glass substrate 200 is configured with an OLED component 210. The mask 100 is configured with a hollow area 110 having a dimension corresponding to the OLED component 210. A gap 300 is formed between a non-hollow area 120 of the mask 100 and the glass substrate 200. The glass substrate 200 is configured with a groove 220 corresponding to the gap 300. The mask 100 is configured with a pillar 130 on one side of the mask 100 facing toward the glass substrate 200. When the mask 100 is bonded with the glass substrate 200, the pillar 130 inserts into the groove 220.

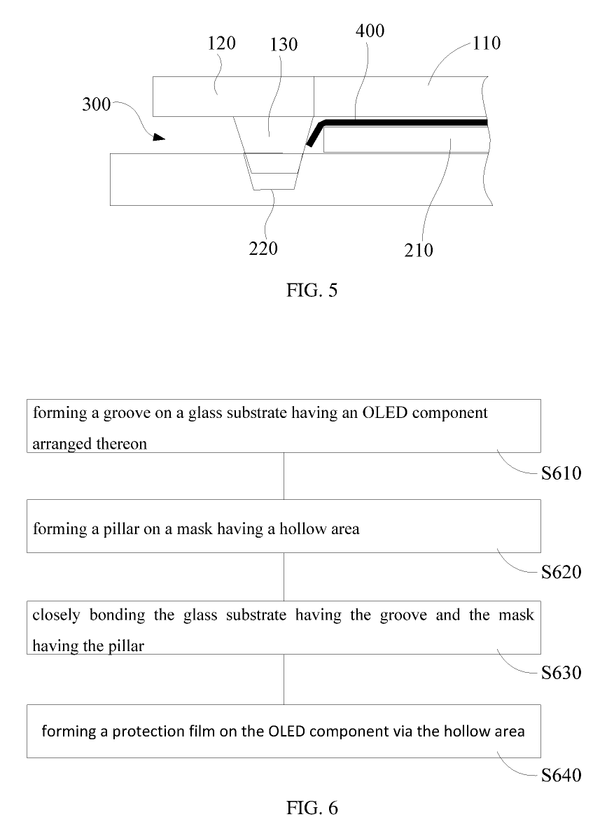

FIG. 5 is a schematic view of the OLED protection film formed by the package structure in accordance with one embodiment. When the OLED component 210 is formed with a protection film 400, the pillar 130 on the mask 100 is configured to block the protection film 400 to prevent the protection film 400 from overly extending toward the gap 300. The protection film 400 can only extend until the pillar 130 (see right side of the pillar 130). In this way, the extension length and the extension location of the protection film 400 have been greatly limited.

Preferably, the pillar 130 on the mask 100 is formed by depositing an inorganic material layer on the mask 100, and by applying the corresponding exposure, lithography, and etching processes. The above processed may be conceived by persons skilled in the art, and thus the detailed description are omitted hereinafter. The inorganic material may be SiN, SiO, SiON, and so on.

In the embodiment, the cross section of the pillar 130 on the mask 100 is trapezoid-shaped. The shape of the groove 220 may engage with the shape of the pillar 130. In other embodiments, the shape of the cross section of the pillar 130 on the mask 100 may be different with the above.

Preferably, the groove 220 on the glass substrate 200 may be configured to surround a rim of the OLED component 210, and a depth of the groove is in a range from 10 um to 20 um. After determining the location and the dimension of the OLED component 210 on the OLED component 210, the etching process is adopted to form the reverse-trapezoid-shaped groove 220 having the depth ranging from 10 um to 20 um to surround the OLED component 210 on the glass substrate.

Further, when the pillar 130 is inserted into the groove 220, the mask 100 bonds with the OLED component 210. A height (H) of the pillar 130 is smaller than a sum of a thickness (T) of the OLED component 210 and a depth (D) of the groove 220 on the glass substrate 200.

In the embodiment, the PECVD process may be adopted to form the protection film 400 made by inorganic materials, such as SiN, SiO, and SiON.

The PECVD adopts microwave or radio frequency to form local plasma from gas ionization. The chemical activity of plasma is very strong, and may react easily. Thus, a thin film may be deposited on the substrate. In order to conduct the chemical reactions under lower temperature, the plasma is adopted. This kind of CVD is referred as PECVD, which is characterized by attributes, such as low temperature, fast deposition rate, good film quality, less pinhole, and may not be cracked easily.

In view of the above, the groove and the pillar that can be engaged with one other are configured on the glass substrate and the mask. The pillar may prevent the protection film from extending toward a gap between the glass substrate and the mask during the OLED protection film is formed. The package structure of the OLED protection film may narrow down the black frame in the rim of the lighting surface, and contributes to the narrow-border design.

FIG. 6 is a schematic view of the package method of the OLED protection film in accordance with one embodiment. The method includes, but not limited to, the steps below.

In step S610, forming a groove on a glass substrate having an OLED component arranged thereon.

In step S610, the groove 220 on the glass substrate 200 may be configured to surround a rim of the OLED component 210, and a depth of the groove is in a range from 10 um to 20 um. After determining the location and the dimension of the OLED component 210 on the OLED component 210, the etching process is adopted to form the reverse-trapezoid-shaped groove 220 having the depth ranging from 10 um to 20 um to surround the OLED component 210 on the glass substrate.

In step S620, forming a pillar on a mask having a hollow area. The dimension of the hollow area correspond to the dimension of the OLED component. A cross section of the pillar on the mask is trapezoid-shaped. The shape of the groove may engage with the shape of the pillar, i.e., trapezoid-shaped. In other embodiments, the shape of the cross section of the pillar 130 on the mask 100 may be different from the trapezoid-shaped.

The pillar on the mask is formed by depositing an inorganic material layer on the mask, and by applying the corresponding exposure, lithography, and etching processes. The above processed may be conceived by persons skilled in the art, and thus the detailed description are omitted hereinafter. The inorganic material may be SiN, SiO, SiON, and so on.

It is to be noted that the sequence of step S610 and S620 may be reverted. That is, The groove on the glass substrate may be formed before or after the pillar is formed on the mask.

In step S630, bonding the glass substrate having the groove and the mask having the pillar. The pillar is inserted into the groove, and the mask bonded with the OLED component closely. A gap is formed between the non-hollow area of the mask and the glass substrate.

Further, in order to closely bond the mask with the OLED component, a height (H) of the pillar 130 is smaller than a sum of a thickness (T) of the OLED component 210 and a depth (D) of the groove 220 on the glass substrate 200, as shown in FIG. 3.

In step S640, forming a protection film on the OLED component via the hollow area.

In step S640, the pillar is configured to block the protection film. FIG. 5 is a schematic view of the OLED protection film formed by the package structure in accordance with one embodiment.

When the OLED component 210 is formed with a protection film 400, the pillar 130 on the mask 100 is configured to block the protection film 400 to prevent the protection film 400 from overly extending toward the gap 300. The protection film 400 can only extend until the pillar 130 (see right side of the pillar 130). In this way, the extension length and the extension location of the protection film 400 have been greatly limited.

In the embodiment, the PECVD process may be adopted to form the protection film 400 made by inorganic materials, such as SiN, SiO, and SiON.

The PECVD adopts microwave or radio frequency to form local plasma from gas ionization. The chemical activity of plasma is very strong, and may react easily. Thus, a thin film may be deposited on the substrate. In order to conduct the chemical reactions under lower temperature, the plasma is adopted. This kind of CVD is referred as PECVD, which is characterized by attributes, such as low temperature, fast deposition rate, good film quality, less pinhole, and may not be cracked easily.

In view of the above, by configuring the groove and the pillar on the glass substrate and the mask, the pillar may prevent the protection film from extending toward a gap between the glass substrate and the mask when the OLED protection film is formed. The package structure of the OLED protection film may narrow down the black frame in the rim of the lighting surface, and contributes to the narrow-border design.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A package structure of organic light emitting diode (OLED) protection film, comprising:
a mask and a glass substrate having at least one OLED component;
the mask being configured with a hollow area having a dimension corresponding to the dimension of the OLED component, a gap being formed between a non-hollow area of the mask and the glass substrate, a groove being configured on the glass substrate and a location of the groove corresponding to the gap, a pillar being configured at one side of the mask facing toward the glass substrate, the pillar being inserted into the groove when the mask and the glass substrate being aligned and bonded;
when the protection film being formed on the OLED component, the pillar being configured to block the protection film;
wherein the pillar on the mask is formed by depositing an inorganic material layer on the mask, and by applying exposure, lithography, and etching processes, a cross section of the pillar on the mask is trapezoid-shaped, and a shape of the groove on the glass substrate adapts to the shape of the pillar.

2. A package structure of organic light emitting diode (OLED) protection film, comprising:
a mask and a glass substrate having at least one OLED component;
the mask being configured with a hollow area having a dimension corresponding to the dimension of the OLED component, a gap being formed between a non-hollow area of the mask and a glass substrate, a groove being configured on the glass substrate and a location of the groove corresponds to the gap, a pillar being configured at one side of the mask facing toward the glass substrate, the pillar being inserted into the groove when the mask and the glass substrate being aligned and bonded;
when the protection film being formed on the OLED component, the pillar being configured to block the protection film.

3. The package structure as claimed in claim 2, wherein the pillar on the mask is formed by depositing a material layer on the mask, and by applying exposure, lithography, and etching processes.

4. The package structure as claimed in claim 3, wherein the pillar is formed by inorganic material.

5. The package structure as claimed in claim 2, wherein a cross section of the pillar on the mask is trapezoid-shaped.

6. The package structure as claimed in claim 5, wherein a shape of the groove on the glass substrate adapts to the shape of the pillar.

7. The package structure as claimed in claim 4, wherein the groove on the glass substrate is configured to surround a rim of the OLED component.

8. The package structure as claimed in claim 7, wherein a depth of the groove is in a range from 10 um to 20 um.

9. The package structure as claimed in claim 4, wherein a height of the pillar is smaller than a sum of a thickness of the OLED component and a depth of the groove on the glass substrate such that the mask is closely bonded with the OLED component when the pillar inserts into the groove.

10. The package structure as claimed in claim 4, wherein the inorganic material comprises SiN, SiO, and SiON.

11. A package method of OLED protection film, comprising:
forming a groove on a glass substrate having an OLED component arranged thereon;
forming a pillar on a mask having a hollow area, a dimension of the hollow area correspond to the dimension of the OLED component;
closely bonding the glass substrate having the groove and the mask having the pillar, when the pillar inserted into the groove, and the mask closely bonded with the OLED component, a gap formed between a non-hollow area on the mask and the glass substrate;
forming a protection film on the OLED component via the hollow area;
wherein the pillar is configured to block the protection film.

12. The package method as claimed in claim 11, wherein the pillar on the mask is formed by depositing a material layer on the mask, and by applying exposure, lithography, and etching processes.

13. The package method as claimed in claim 12, wherein the pillar is formed by inorganic material.

14. The package method as claimed in claim 11, wherein a cross section of the pillar on the mask is trapezoid-shaped.

15. The package method as claimed in claim 14, wherein a shape of the groove on the glass substrate adapts to the shape of the pillar.

16. The package method as claimed in claim 13, wherein the groove on the glass substrate is configured to surround a rim of the OLED component.

17. The package method as claimed in claim 16, wherein a depth of the groove is in a range from 10 um to 20 um.

18. The package method as claimed in claim 13, wherein a height of the pillar is smaller than a sum of a thickness of the OLED component and a depth of the groove on the glass substrate such that the mask is closely bonded with the OLED component when the pillar inserts into the groove.

19. The package method as claimed in claim 13, wherein the inorganic material comprises SiN, SiO, and SiON.
